(19) United States
(12) Patent Application Publication
(10) Pub. No.: US 2008/0169064 A1
(43) Pub. Date: Jul. 17, 2008

(54) Surface-treating apparatus

(75) Inventors: Seiji Samukawa, Miyagi (JP); Fumihiko Oda, Hyogo (JP); Yukihiro Morimoto, Hyogo (JP)

Correspondence Address: FRISHAUF, HOLTZ, GOODMAN & CHICK, PC, 220 Fifth Avenue, 16TH Floor, NEW YORK, NY, 10001-7708, US

(73) Assignees: USHIO DENKI KABUSHIKI KAISHA, Tokyo (JP); TOHOKU UNIVERSITY, Sendai-shi (JP)

(21) Appl. No.: 12/006,375

(22) Filed: Jan. 2, 2008

(30) Foreign Application Priority Data
Jan. 11, 2007 (JP) JP2007-003612
Aug. 31, 2007 (JP) JP2007-225944

(51) Int. Cl. H01L 21/306

(52) U.S. Cl. 156/345.1

(57) ABSTRACT

Provided is a surface-treating apparatus making use of a neutral particle beam, by which a high-quality surface treatment is fundamentally conducted, and a high surface treatment rate is achieved. The surface-treating apparatus serves to conduct a surface treatment of an object to be treated, which is arranged in a vacuum treatment chamber, by a neutral particle beam, and is equipped with a light source for irradiating the object to be treated with light. In the surface-treating apparatus, the light applied to the object to be treated is preferably light including rays having a wavelength of 380 nm or shorter. An illuminance of the rays having a wavelength of 380 nm or shorter on the surface to be treated of the object to be treated is preferably 7 mW/cm² or higher. The light source is preferably a xenon flash lamp, and an illuminance of the light on the surface to be treated of the object to be treated is preferably 20 mW/cm² or higher.

### BACKGROUND OF THE INVENTION

1. Field of the Invention

The present invention relates to a surface-treating apparatus for processing an object to be treated using a neutral particle beam obtained by neutralizing positive ions or negative ions generated in, for example, plasma, and particularly to a surface-treating apparatus such as an etching system for removing exposed portions of, for example, a silicon wafer, which are not covered with a photoresist after a pattern is formed with the photoresist on the silicon wafer.

2. Description of the Related Art

In recent years, there has been a demand for forming a finer processing pattern of a photoresist in processing of, for example, a silicon wafer, and a high-quality etch processing has been groped attending on this. For example, a plasma etching system is used in such etch processing. As the plasma etching system, is known a reactive ion etching system (RIE system) by which a surface to be treated of an object to be treated, which is composed of a silicon wafer, is irradiated with composite particles composed of ions, radicals, neutral particles, photons and/or the like. However, damage by etching may possibly occur on the object to be treated according to the kinds of particles making up the composite particles.

In order to solve the problem of this damage by etching, there has been proposed an etching system making use of a neutral particle beam, by which only neutral particles are applied (see Japanese Patent Application Laid-Open No. 2003-158099). According to etching by the neutral particle beam, high processing precision is achieved, and occurrence of damage by etching is inhibited, so that high-quality etch processing can be conducted.

The reason for it is that only the neutral particles among the ions, radicals, neutral particles and photons compositely applied in the ordinary ion etching are applied, and so damage is little compared with the ion etching. The etching by neutral particle beam is particularly preferably used in ultrafine processing of a processing line width of about 30 nm or less.

Japanese Patent Application Laid-Open No. 2003-158099 discloses that a first electrode having apertures is held in a higher potential state on a plus side than a second electrode arranged in opposition to the first electrode, whereby negative ions in plasma are accelerated toward the first electrode, and are thereby passed through the apertures in the first electrode while striking the peripheral walls thereof to be neutralized, so as to emit neutral particles.

However, this etching system is so constructed that the resultant neutral particles are generated by the negative ions alone, so that the generation efficiency of the neutral particles is poor. As a result, there is a problem that an etching treatment rate becomes a tenth or lower compared with the case where the ordinary ion etching is conducted, and so a high etching treatment rate cannot be achieved.

In order to solve such a problem, there have been proposed etching systems by which high-frequency electric power is applied to a first electrode having apertures, whereby both positive ions and negative ions can be neutralized, and consequently the generation efficiency of neutral particles are improved (see Japanese Patent Application Laid-Open Nos. 2005-259873 and 2005-260195).

However, these etching systems also involve a problem that a sufficient etching treatment rate cannot be achieved compared with the RIE system by the composite particles.

On the other hand, Japanese Patent Application Laid-Open No. 2001-35833 discloses a technique that photons are applied during a plasma etching treatment or before or after the treatment. In this technique, however, etching is conducted by composite particles in plasma, and the photons are applied for the purpose of removing residues of the etching by the composite particles and it could not be intended to improve the treatment efficiency of the etching itself.

In the etching systems disclosed in Japanese Patent Application Laid-Open Nos. 2005-259873 and 2005-260195, light is screened by the first electrode having the apertures, so that light (photon) is not emitted from a neutral particle beam source.

### SUMMARY OF THE INVENTION

The present invention has been made in view of the foregoing circumstances and has as its object the provision of a surface-treating apparatus making use of a neutral particle beam, by which a high-quality surface treatment is fundamentally conducted, and a high surface treatment rate is achieved.

According to the present invention, there is provided a surface-treating apparatus for conducting a surface treatment of an object to be treated, which is arranged in a vacuum treatment chamber, by a neutral particle beam, comprising:

a light source for irradiating the object to be treated with light.

In the surface-treating apparatus according to the present invention, the light applied to the object to be treated may preferably be light including rays having a wavelength of 380 nm or shorter.

In the surface-treating apparatus according to the present invention, an illuminance of the rays having a wavelength of 380 nm or shorter on the surface to be treated of the object to be treated may preferably be 7 mW/cm² or higher.

In the surface-treating apparatus according to the present invention, it may be preferable that the light source be a xenon flash lamp, and an illuminance of the light on the surface to be treated of the object to be treated be 20 mW/cm² or higher.

According to the surface-treating apparatus of the present invention, the light source is provided, and the object to be treated is irradiated with the light from this light source upon surface treatment by the neutral particle beam, so that a high surface treatment rate can be achieved while carrying out a high-quality surface treatment.

This reason is presumed to be attributable to the fact that the object to be treated absorbs the light from the light source, whereby an electron deficiency is generated at a portion of the object to be treated, in which the light is absorbed, thereby accelerating a reaction rate of the etching treatment.

Further features of the present invention will become apparent from the following description of exemplary embodiments with reference to the attached drawings.

### BRIEF DESCRIPTION OF THE DRAWINGS

FIG. 1 schematically illustrates an exemplary surface-treating apparatus according to the present invention.

FIG. 2 diagrammatically illustrates the results of Experimental Example 1 and Comparative Experimental Example 1.

FIG. 3 diagrammatically illustrates the results of Experimental Example 2 and Comparative Experimental Examples 2 and 3.

FIG. 4 diagrammatically illustrates the result of Experimental Example 3.

### DESCRIPTION OF THE EMBODIMENTS

The present invention will hereinafter be specifically described.

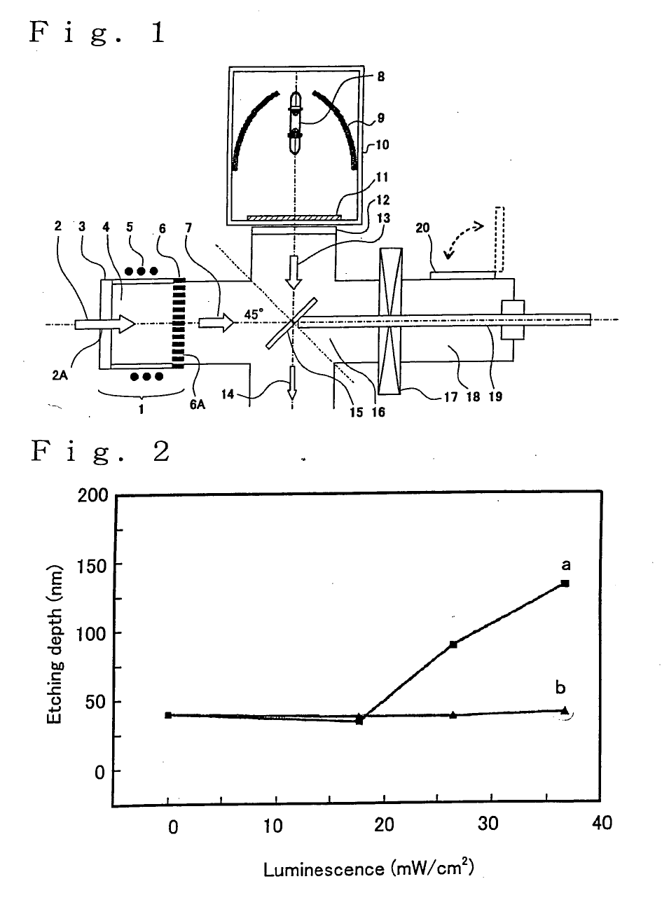

FIG. 1 schematically illustrates an exemplary surface-treating apparatus according to the present invention.

This surface-treating apparatus demonstrates an etching system for removing exposed portions of a silicon wafer, which are not covered with a photoresist after a pattern is formed with the photoresist on the silicon wafer.

This etching system is equipped with a neutral particle beam source 1 and a light source 8. A surface to be treated of the silicon wafer, which is an object 15 to be treated and arranged in a vacuum treatment chamber (process chamber) 16 in a dark state, is irradiated with a neutral particle beam 7 generated from the neutral particle beam source 1 in a state that the surface to be treated of the object 15 to be treated has been irradiated with light 13, whereby a surface treatment is conducted on this object 15 to be treated.

The neutral particle beam source 1 is formed by an ICP chamber (inductive coupled plasma chamber) 4, on the outer periphery of which an inductive coupled coil 5 is arranged, a downstream side electrode 6 arranged so as to partition a space into the ICP chamber 4 and the process chamber 16 and having a plurality of apertures 6A, and an upstream side electrode 3 arranged in opposition to this downstream side electrode 6.

Since the ICP chamber 4 of the neutral particle beam source 1 and the process chamber 16 are partitioned by the downstream side electrode 6, a state that a pressure difference is made between both chambers 4 and 16 can be retained. The pressure of the ICP chamber 4 is, for example, 1 Pa, and the pressure of the process chamber 16 is, for example, 0.1 Pa.

In FIG. 1, an arrow 14 indicates a pressure-reducing passage for reducing the pressure within the process chamber 16 by a vacuum pump or the like.

The system is so constructed that the inductive coupled coil 5 is connected to a high-frequency power source (not illustrated), the downstream side electrode 6 is also connected to a high-frequency power source (not illustrated), the upstream side electrode 3 is connected to a dc power source (not illustrated), and a voltage is applied between the downstream side electrode 6 and the upstream side electrode 3.

A ratio of the thickness of the downstream side electrode 6 to the aperture diameter of each aperture 6A in the downstream side electrode 6 is preferably of the order of, for example, 10:1, and the apertures 6A are preferably formed in a proportion of about a half of the overall area of one surface of the downstream side electrode 6.

A gas-introducing port 2A, through which an etchant gas 2 is introduced, is provided in the upstream side electrode 3.

Examples of the etchant gas to be introduced include Cl₂, SF₆, CHF₃, CF₄, Ar, O₂, N₂, C₄F₈, CF₃I and C₂F₄.

The light source 8 is arranged in a lamp house 10, and a condenser mirror 9 is provided around the light source 8 so as to emit light near parallel rays on the surface to be treated of the object 15 to be treated through a window 12 composed of synthetic quartz or calcium fluoride.

In FIG. 1, reference numeral 11 indicates a filter arranging part, on which a wavelength-regulating filter is arranged as needed, when it is intended to emit light 13, whose wavelength is regulated.

In the present invention, the light 13 applied to the object 15 to be treated is preferably light including rays having a wavelength of 380 nm or shorter.

The reason for it is that when the object 15 to be treated is composed of, for example, silicon, a penetration length of such light into silicon is small, specifically, the penetration length of the light into the object 15 to be treated is about 30 nm or shorter from the surface to be treated of the object 15 to be treated when the surface to be treated is irradiated with rays having a wavelength of 200 to 380 nm, so that the light is absorbed at a high density in an extreme surface layer to the depth of 30 nm from the surface to be treated of the object 15 to be treated, and consequently the extreme surface layer to be etched by the neutral particle beam 7 can be activated to surely accelerate a reaction rate. The depth of etching by the neutral particle beam 7 is generally presumed to be from one atomic layer to several atomic layers in terms of an etched depth that one neutral particle exerts an etching action on the object 15 to be treated, or about 30 nm reduced to the depth. Accordingly, in order to attain a deep etched depth extending over, for example, several hundreds nanometers, it is only necessary to continuously apply the neutral particle beam 7 over a necessary period of time.

When a range (approximately, a range of the light penetration length), in which the light is absorbed in the object to be treated, extends beyond a range intended to conduct etching by neutral particle beam, there is a possibility that undesirable damage may be formed in the object to be treated. In particular, there is a possibility that damage capable of exerting a fatal influence on the performance of a device finally fabricated may be formed when the damage is formed over a range of at least a processing line width. However, when the light 13 applied to the object 15 to be treated is light including rays having a wavelength of 380 nm or shorter, the formation of unexpected damage is inhibited because the penetration length of the light including rays having a wavelength of 380 nm or shorter into silicon is about 30 nm as described above, which falls within the range intended to conduct etching.

When the light 13 applied to the surface to be treated of the object 15 to be treated is light composed of only rays having a wavelength longer than 380 nm, the penetration length of the light into silicon is great, so that the density of the light absorbed in a surface portion of the object to be treated is low, and so not only the effect to improve the etching treatment rate is scarcely achieved, but also damage is formed in the object to be treated.

From the above, it is particularly preferable that light composed of only rays having a wavelength of 380 nm or shorter, which corresponds to the light penetration length of 30 nm or shorter, be applied in order to achieve high etching treatment rate without losing merits in the etching process by neutral particle beam that a high quality etching can be performed.

An illuminance of the light composed of only rays having a wavelength of 380 nm or shorter on the surface to be treated of the object 15 to be treated is preferably 7 mW/cm² or higher. The surface to be treated of the object 15 to be treated is irradiated at the illuminance within the above range with the light composed of only rays having a wavelength of 380 nm or shorter, whereby the etching treatment rate can be surely made high.

When the surface to be treated of the object to be treated is irradiated with light, it is considered that an action of forming an electron deficiency at a portion (hereinafter also referred to as “light-absorbed site”) of the object to be treated, in which the light is absorbed to activate the portion, an action of exciting the electronic state of the light-absorbed site to activate the site, and an action of exciting neutral particles after or before arrived at the object to be treated to activate them are achieved. Therefore, when the object to be treated is irradiated with the light, a probability (etching yield) of etching a substance forming the object to be treated by the neutral particles arrived at the surface to be treated of the object to be treated, and separating and discharging an etched product etched off from the object to be treated can be made high. After all, it is presumed that a high etching treatment rate can be achieved compared with the case where the irradiation of the light is not conducted.

The effect to improve the etching treatment rate is brought about only when the phenomenon such as the formation of the deficiency by the irradiation of the light occurs in a range that individual neutral particles can exert an influence, and so it is presumed that light absorbed in a place deeper than the surface of the object to be treated, for example, a site deeper than 30 nm from the surface of a silicon wafer does not contribute to the improvement in the etching treatment rate at all.

Incidentally, for example, when the interior of the lamp house 10 is filled with air, rays having a wavelength of 200 nm or shorter among rays emitted from the light source 8 are absorbed in the air, so that the light emitted to the process chamber 16 does not include the rays having a wavelength of 200 nm or shorter.

In the present invention, an illuminance of the light including the rays having a wavelength of 380 nm or shorter applied to the surface to be treated of the object 15 to be treated from the light source 8 is preferably 20 mW/cm² or higher.

This light has the illuminance of 20 mW/cm² or higher, whereby the illuminance of the rays having a wavelength of 380 nm or shorter on the surface to be treated of the object 15 to be treated can be controlled to 7 mW/cm² or higher, and a sufficient amount of the light is absorbed at a flux of 1 mA/cm² that is etching conditions by the general neutral particle beam. As a result, the etching treatment rate can be surely made high.

Here, the illuminance of the light 13 applied to the surface to be treated of the object 15 to be treated is measured as an integrated value at all emission wavelengths by means of a calorimeter.

Examples of the light source capable of strongly obtaining the light including such rays having a wavelength of 380 nm or shorter include lamps such as a short-arc xenon flash lamp, high current density-driving short-arc flash lamps with a rare gas (krypton (Kr) gas, argon (Ar) gas, xenon (Xe) gas or a mixed gas thereof) enclosed therein, high current density-driving long-arc flash lamps with a rare gas (Kr gas, Ar gas, Xe gas or a mixed gas thereof) enclosed therein, a low-pressure mercury lamp, a high-pressure mercury lamp, a xenon short-arc lamp and various excimer lamps.

Besides the lamps, a laser light source such as a YAG laser (triple harmonics=355 nm, quadruple harmonics=266 nm), an ArF excimer laser (193 nm), a KrF excimer laser (248 nm), an Ar laser (double harmonics=244 nm), a dye laser (double harmonics=variable in wavelength at about 200 to 330 nm), a nitrogen laser (337 nm) or a He—Cd laser (325 nm) may also be used.

Here, the term “capable of strongly obtaining the light including rays having a wavelength of 380 nm or shorter” means that rays having a wavelength of 380 nm or shorter are emitted at a high illuminance.

For example, when a short-arc xenon flash lamp is used as the light source, for example, a current density and a pressure of xenon enclosed are controlled to 1 to 100 kA/cm² and 10 to 500 kPa, respectively, whereby the light including rays having a wavelength of 380 nm or shorter can be obtained.

In the etching system illustrated in FIG. 1, the object 15 to be treated is arranged in such a manner that the surface to be treated forms an angle of 45° with an emitting direction of the neutral particle beam 7, and an angle formed between an emitting direction of the light 13 from the light source 8 and the emitting direction of the neutral particle beam 7 is controlled to 90°. However, no particular limitations are imposed on these conditions.

In FIG. 1, reference numeral 18 indicates a load-lock chamber partitioned from the process chamber 16 by a gate valve 17 for conducting exchange and arrangement of the object to be treated without opening the process chamber 16 to the air, and reference numeral 19 designates a transfer bar for arranging the object 15 to be treated, which is carried in through an opening 20 for carrying the object to be treated therein, at the surface treatment position.

In such an etching system, the interior of the process chamber 16 is first evacuated by operating the vacuum pump, and the etchant gas 2 is then introduced in the ICP chamber 4 of the neutral particle beam source 1 from the gas-introducing port 2A. A high high-frequency voltage of, for example, about 13.56 MHz is then applied to the inductive coupled coil 5 from the high-frequency power source connected to the inductive coupled coil 5, thereby generating an induction field within the ICP chamber 4 of the neutral particle beam source 1 and further inducing an induced electromotive field by time changes of this magnetic field. On the other hand, the etchant gas 2 introduced within the ICP chamber 4 of the neutral particle beam source 1 is ionized by electrons excited by this induced electromotive field to generate high-density plasma. The plasma generated at this time is plasma composed mainly of positive ions and electrons.

The application of the high-frequency voltage by the high-frequency power source connected to the inductive coupled coil 5 is then stopped for 50 μsec to lower the temperature of the electrons via inelastic collision and cause the electrons to adhere to the remaining etchant gas, thereby generating negative ions. After the application of the high-frequency voltage by the high-frequency power source connected to the inductive coupled coil 5 is stopped for 50 μsec, the high-frequency voltage is applied again for 50 μsec by the high-frequency power source, thereby repeating the above-described cycle to form plasma in a state that negative ions coexist with the positive ions.

The dc power source connected to the upstream side electrode 3 and the high-frequency power source connected to the downstream side electrode 6 are used to apply a voltage between these electrodes, thereby forming a potential difference. The positive ions and negative ions within the neutral particle beam source 1 are accelerated toward the downstream side electrode 6 by this potential difference to introduce them into the apertures 6A formed in the downstream side electrode 6 and pass them through the apertures 6A while neutralizing them by causing them to strike the inner walls of the apertures 6A so as to eliminate their charges or by charge exchange with the etchant gas remaining in the apertures 6A, thereby generating neutral particles to emit a neutral particle beam 7 by the neutral particles in the interior of the process chamber 16. This neutral particle beam 7 goes straight in the process chamber 16 to strike the surface to be treated of the object 15 to be treated.

On the other hand, light is emitted from the light source 8 at the same time as the irradiation of this neutral particle beam 7 and condensed by the condenser mirror 9, and the surface to be treated of the object 15 to be treated is irradiated with the condensed light 13 emitted through the window 12 provided in the process chamber 16.

The irradiation of the light 13 may be conducted over the whole time of the etching treatment or for only a part of the time.

### EXPERIMENTAL EXAMPLES

Experimental Examples conducted on the surface-treating apparatus according to the present invention will hereinafter be described.

### Experimental Example 1

### Example where Light Including Rays Having a Wavelength of 380 Nm or Shorter was Applied

An etching system was produced in accordance with FIG. 1 to conduct the following experiment without using any wavelength-regulating filter.

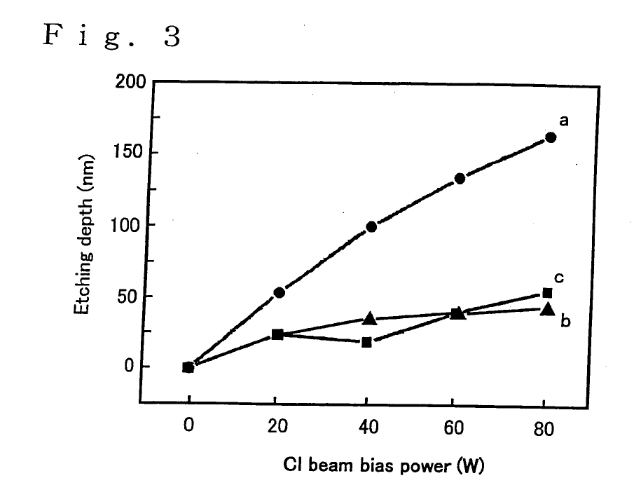

The illuminance of the light on a surface to be treated of an object to be treated was varied to 0 mW/cm², 18 mW/cm², 26 mW/cm² and 37 mW/cm², and other conditions were set as follows to conduct an etching treatment, thereby measuring an etched depth by means of an atomic force microscope (AFM) The result is illustrated by a in FIG. 2.

### (Conditions)

Light source: Xenon flash lamp, interelectrode length: 5 mm, inner diameter of light emitting tube: 10 mm, pressure of xenon enclosed: 80 kPa, current density: 10 kA/cm², pulsed lighting frequency: 8 Hz, time width of current pulse: 25 μsec (FWHM).

Etching time: 20 minutes.

Electric power inputted into downstream side electrode: 600 kHz, 60 W.

Etchant gas: Cl₂ gas.

### Comparative Experimental Example 1

### Example where Light Including No Ray Having a Wavelength of 380 Nm or Shorter was Applied

An experiment was conducted in the same manner as in Experimental Example 1 except that a colored glass filter screening rays having a wavelength of 380 nm or shorter was used as the wavelength-regulating filter. The result is illustrated by b in FIG. 2.

From Experimental Example 1 described above, it was confirmed that when the light applied to the surface to be treated of the object to be treated is light including rays having a wavelength of 380 nm or shorter and has an illuminance of 20 mW/cm² or higher, a great etched depth is achieved according to the intensity of the illuminance.

On the other hand, from Comparative Experimental Example 1, it was confirmed that when the light, in which rays having a wavelength of 380 nm or shorter are screened, is applied to the surface to be treated of the object to be treated, no influence is exerted on the etched depth even if the illuminance is 20 mW/cm² or higher.

From the above, it is clearly known that when the light applied to the surface to be treated of the object to be treated is light including rays having a wavelength of 380 nm or shorter, and the amount of energy applied to unit area is a certain value or higher, a great etched depth is achieved according to the amount of energy. This reason is considered to be attributable to the fact that an electron deficiency is formed at the surface to be treated of the object 15 to be treated by the irradiation of the specific light to achieve a high etching treatment rate, and so a great etched depth can be achieved within a certain period of time.

From the results of the above-described experimental examples, it is also presumed that when the etching time in the conditions set is made long, and/or the lighting frequency of the xenon flash lamp making up the light source is made high, a great etched depth is achieved according to the intensity of the illuminance when the light applied to the surface to be treated of the object to be treated is light including rays having a wavelength of 380 nm or shorter and has an illuminance of 20 mW/cm² or higher.

### Experimental Example 2

### Example where Light Including Rays Having a Wavelength of 380 Nm or Shorter was Applied

An etching system was produced in accordance with FIG. 1 to conduct the following experiment without using any wavelength-regulating filter.

The electric power inputted into the downstream side electrode was varied to 0 W, 20 W, 40 W, 60 W and 80 W at 600 kHz, and other conditions were set as follows to conduct an etching treatment, thereby measuring an etched depth by means of an atomic force microscope (AFM). The energy of a Cl neutral particle beam becomes higher as the electric power inputted into the downstream side electrode increases. The result is illustrated by a in FIG. 3.

### (Conditions)

Light source: Xenon flash lamp, interelectrode length: 5 mm, inner diameter of light emitting tube: 10 mm, pressure of xenon enclosed: 80 kPa, current density: 10 kA/cm², pulsed lighting frequency: 8 Hz, time width of current pulse: 25 μsec (FWHM).

Illuminance on the surface to be treated of the object to be treated: 37 mW/cm².

Etching time: 20 minutes.

Etchant gas: Cl₂ gas.

### Comparative Experimental Example 2

### Example where Light Including No Ray Having a Wavelength of 380 Nm or Shorter was Applied

An experiment was conducted in the same manner as in Experimental Example 2 except that a colored glass filter screening rays having a wavelength of 380 nm or shorter was used as the wavelength-regulating filter. The result is illustrated by b in FIG. 3.

### Comparative Experimental Example 3

### Example where Light was not Applied at all

An experiment was conducted in the same manner as in Experimental Example 2 except that irradiation of light on the surface to be treated of the object to be treated was not conducted. The result is illustrated by c in FIG. 3.

From Experimental Example 2 described above, it was confirmed that when the light applied to the surface to be treated of the object to be treated is light including rays having a wavelength of 380 nm or shorter, an etched depth according to the intensity of the electric power inputted into the downstream side electrode is achieved. It is known from this fact that a higher etching treatment rate is achieved as the electric power inputted into the downstream side electrode is increased.

On the other hand, from Comparative Experimental Examples 2 and 3, it was confirmed that when light is not applied at all, and when the light, in which rays having a wavelength of 380 nm or shorter are screened, is applied to the surface to be treated of the object to be treated, only a certain etched depth is achieved irrespective of the intensity of the electric power inputted into the downstream side electrode, namely, an etching treatment rate cannot be improved even if the electric power inputted into the downstream side electrode is increased.

### Experimental Example 3

### Example where Light Composed of Only Rays Having a Wavelength of 380 Nm or Shorter was Applied

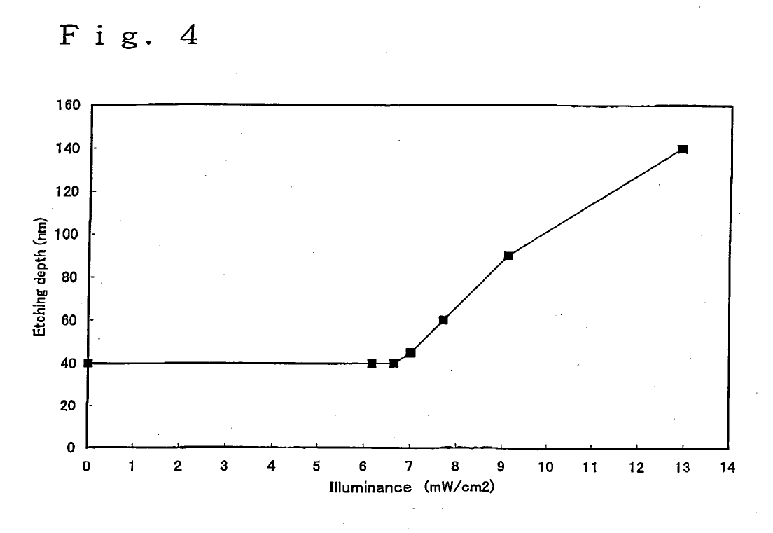

An experiment was conducted in the same manner as in Experimental Example 1 except that an ultraviolet ray-permeable and visible ray-impermeable filter blocking rays having a wavelength of 380 nm or longer was used as the wavelength-regulating filter, and the illuminance of the light having a wavelength of 380 nm or shorter on a surface to be treated of an object to be treated was varied to 0 mW/cm², 6.17 mW/cm², 6.65 mW/cm², 7.0 mW/cm², 7.7 mW/cm², 9.1 mW/cm² and 12.9 mW/cm². The result is illustrated in FIG. 4.

From Experimental Example 3 described above, it was confirmed that when the light applied to the surface to be treated of the object to be treated is light composed of only rays having a wavelength of 380 nm or shorter and has an illuminance of 7 mW/cm² or higher, a high etched depth is achieved according to the intensity of the illuminance. It is known from this fact that when the light applied to the surface to be treated of the object to be treated is light composed of only rays having a wavelength of 380 nm or shorter, and the amount of energy applied to unit area is a certain value or higher, a higher etching treatment rate according to the amount of energy is achieved.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

What is claimed is:

1. A surface-treating apparatus for conducting a surface treatment of an object to be treated, which is arranged in a vacuum treatment chamber, by a neutral particle beam, comprising:
a light source for irradiating the object to be treated with light.

2. The surface-treating apparatus according to claim 1, wherein the light applied to the object to be treated is light including rays having a wavelength of 380 nm or shorter.

3. The surface-treating apparatus according to claim 2, wherein an illuminance of the rays having a wavelength of 380 nm or shorter on the surface to be treated of the object to be treated is 7 mW/cm² or higher.

4. The surface-treating apparatus according to claim 3, wherein the light source is a xenon flash lamp, and an illuminance of the light on the surface to be treated of the object to be treated is 20 mW/cm² or higher.
